(19) United States
(12) Patent Application Publication
(10) Pub. No.: US 2017/0273218 A1
(43) Pub. Date: Sep. 21, 2017

(54) ELECTRONIC DEVICE AND METHOD OF ASSEMBLING SUCH A DEVICE

(71) Applicant: Delphi International Operations Luxembourg S.A.R.L., Bascharage (LU)

(72) Inventors: Peter Stoermer, Remscheid (DE); Marcel Fruend, Remscheid (DE)

(21) Appl. No.: 15/451,690

(22) Filed: Mar. 7, 2017

(30) Foreign Application Priority Data
Mar. 15, 2016 (FR) 1670105

(51) Int. Cl. H05K 7/20; H05K 1/02; H05K 5/03; H05K 7/14

(52) U.S. Cl. CPC H05K 7/20436; H05K 7/20418; H05K 7/1427; H05K 1/0203; H05K 5/03; H05K 2201/066

(57) ABSTRACT

An electronic device for motor vehicles comprises a heat-conducting housing containing a printed circuit board and an element producing heat mounted on the printed circuit board. The housing comprises a housing base on which the printed circuit board is mounted and comprises a cover opposite to the housing base. A first heat-dissipating metal structure is mounted on the element producing heat, and a second heat-dissipating metal structure, formed as part of the cover of the housing and protruding into the housing, is coupled with the first heat-dissipating metal structure, in such a manner as to facilitate the dissipation of the thermal energy from the element producing heat towards the outside of the housing.

### CROSS-REFERENCE TO RELATED APPLICATION

This application claims the benefit under 35 U.S.C. §119(a) of French Patent Application FR 1670105, filed 15 Mar. 2016, the entire disclosure of which is hereby incorporated herein by reference.

### TECHNICAL FIELD OF INVENTION

This disclosure generally relates to an electronic device for motor vehicles and, more particularly relates to a heat-dissipating device for printed circuit boards.

### BACKGROUND OF INVENTION

The electronic devices for motor vehicles generally comprise electronic components mounted on a printed circuit board. Certain electronic components are components that produce heat. These may be microcontrollers whose data processing speed is such that the microcontroller gets hot during its operations, or again for example, these may be electronic components distributing high electrical currents to the equipment of the vehicle, or yet again simply conducting tracks carrying high currents across the printed circuit board.

In order to cool these components so as to avoid them failing, a known solution is to dissipate their heat by thermally coupling these components directly to a heat-conductive housing of the device. Generally, in order to guarantee a permanent thermal coupling, notably when the vehicle, on-board which the device is carried, is being driven and which is subjected to vibrations, the cover of the housing being used as a radiator for cooling the components is screwed to the printed circuit board in such a manner as to maintain an area of the cover protruding towards the inside of the housing in continuous contact with the component generating heat.

It has been observed that, during the assembly of such devices and equally when such devices are subjected to vibrations when the vehicle on-board which such devices are carried is being driven, the rigidity of the assembly screwed together leads to failures of the cooled components, notably cracking of the solder joints of the components or else damage to the component resulting in a failure of the latter. It has also been observed that such a structure proves to be difficult to upgrade since, generally, during a hardware update of the disposition of the electronic components mounted on the printed circuit board, a new design of the cover of the housing has to be provided in order to adjust the positioning of the protrusions of the cover coming into direct contact with the components producing heat in order to ensure their cooling.

### SUMMARY OF THE INVENTION

An electronic device for motor vehicles comprises a heat-conductive housing containing a printed circuit board and an element producing heat mounted on the printed circuit board. The housing comprises a housing base on which the printed circuit board is mounted and comprises a cover opposite to the housing base. A first heat-dissipating metal structure is mounted on the element producing heat, and a second heat-dissipating metal structure, which is formed as part of the cover of the housing and protruding into the housing, is coupled with the first heat-dissipating metal structure, in such a manner as to facilitate the dissipation of the thermal energy from the element producing heat towards the outside of the housing.

The first heat-dissipating metal structure and the second heat-dissipating metal structure may each comprise a plurality of fins interdigitated with one another. The interdigitated heat-dissipating fins may comprise oblique sidewalls thermally coupled to one another. The first heat-dissipating metal structure may comprise fewer fins than the second heat-dissipating metal structure. The electronic device may comprise gaps between the interdigitated fins, the said gaps comprising a heat-conductive material in such a manner as to thermally couple the interdigitated fins. The printed circuit board may comprise several first metal structures with heat-dissipating fins for which each height of each first metal structure with fins is adapted to the distance separating the element producing heat from the internal face of the cover of the housing in such a manner as to facilitate the dissipation of the thermal energy from the element producing heat towards the outside of the housing. The cover of the housing may comprise several second metal structures with heat-dissipating fins for which each height of each second metal structure with fins is adapted to the distance separating the element producing heat from the internal face of the cover of the housing in such a manner as to facilitate the dissipation of the thermal energy from the element producing heat towards the outside of the housing. The first heat-dissipating metal structure may be fixed onto the associated element producing heat by means of a heat-conductive adhesive layer. The cover of the housing may comprise heat-dissipating fins on its external surface.

A method of assembling the electronic device for motor vehicles described hereinabove comprises the steps for: supplying a printed circuit board comprising elements producing heat; fixing the printed circuit board onto a housing base; fixing a heat-conductive material onto the elements producing heat; fixing first metal structures with heat-dissipating fins onto the heat-conductive materials placed on the elements producing heat; disposing another heat-conductive material on the fins of the first heat-dissipating metal structures fixed onto the elements producing heat; supplying a heat-conductive housing cover comprising structures with fins protruding towards the inside of the housing; and closing the housing by placing the cover of the housing on the housing base in such a manner as to interdigitate and to thermally couple the structures with fins of the cover of the housing with the structures with fins of the elements producing heat; the thermal coupling being effected by compression of the heat-conductive material previously disposed on the fins of the first heat-dissipating structures between the sides of the interdigitated fins.

### BRIEF DESCRIPTION OF DRAWINGS

Other features, aims and advantages of the invention will become apparent upon reading the detailed description that follows, and with regard to the appended drawings, presented by way of non-limiting example and in which:

FIG. 1 is an exploded schematic perspective and transverse cross-sectional view of an electronic device for motor vehicles according to a first embodiment of the invention;

FIG. 2 is a schematic transverse cross-sectional view of the assembled electronic device in FIG. 1;

FIG. 3 is a schematic transverse cross-sectional view of the electronic device in FIG. 1 for which the arrangement of the electronic components has been modified;

FIG. 4 is a schematic view of the printed circuit board of the electronic device in FIG. 1; and

FIG. 5 is a schematic view of the printed circuit board of the electronic device in FIG. 1 equipped with heat-dissipating structures.

### DETAILED DESCRIPTION

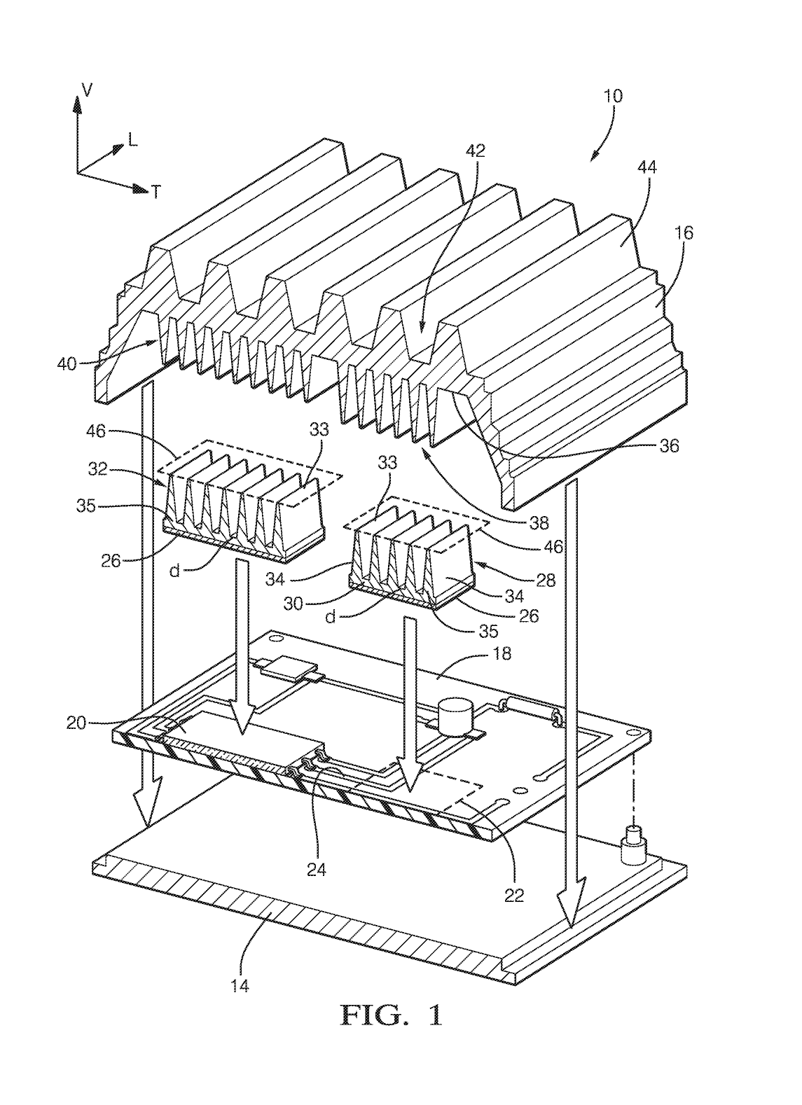

According to FIG. 1 and FIG. 2, an electronic device 10 for vehicles comprises a housing 12 formed by a housing base 14, a cover 16 and a printed circuit board 18 mounted on the housing base 14 inside of the housing 12.

The printed circuit board 18 is equipped with electronic components 20 electrically connected together via conducting tracks 24 such as copper tracks. An electronic component 20 and an area of the printed circuit board traversed by conducting tracks 24 are covered with a first heat-conductive adhesive material 26 such as thermal paste. The first heat-conductive material 26 preferably takes the form of an adhesive strip of the double-sided type. First heat-dissipating metal structures 28 are fixed onto the first heat-conductive materials 26 by virtue of the adhesive properties of the heat-conductive material 26. The electronic component 20 and the area of the printed circuit board 22 traversed by the conducting tracks 24 are elements producing heat and cooled by the first heat-dissipating metal structures 28. Although, in the following part of the presentation of the invention, the electronic device 10 comprises two elements producing heat, it is clear that the invention covers all the embodiments of electronic devices 10 comprising at least one element producing heat 20.

In the following part of the description and in a non-limiting manner, according to FIG. 1, an orthogonal reference frame defines a vertical axis V, a transverse axis T and a longitudinal axis L.

The first heat-dissipating metal structures 28 comprise a base plate 30 with dimensions globally similar to the surface area of the elements producing heat on which heat-dissipating fins extend 32 along the vertical axis V towards the internal face 36 of the cover 16 of the housing 12 opposite to the housing base 14. The fins 32 have a cross-sectional profile across the transverse axis T with a triangular shape. The apex 33 of each fin 32 extends along the longitudinal axis L all the way along the base plate 30. The bases 35 of the fins 32 are spaced out in a transverse direction in a regular manner by a distance d the same order of magnitude as the width of their base 35. The fins 32 therefore have the shape of a prism with a triangular base. Each fin 32 comprises two oblique sidewalls 34 running longitudinally all the way along the base plate. The number of fins 32 is defined so as to cover the whole of the base plate 30. The base plate 30 and the fins 32 form a single element.

The cover 16 of the housing 12 is made of a heat-conductive metal such as aluminium or magnesium. On its internal face 36, opposite to the housing base 14, the cover 16 of the housing 12 comprises second heat-dissipating metal structures 38 forming protrusions towards the inside of the housing 12. The second heat-dissipating metal structures 38 are formed as a single piece with the cover 16 of the housing 12. The second heat-dissipating metal structures 38 also comprise heat-dissipating fins 40 with a regular spacing between them in such a manner as to be able to be interdigitated with the heat-dissipating fins of the first metal structures 32. The second heat-dissipating metal structures 38 have a similar geometrical shape to the first heat-dissipating metal structures 28; the fins 40 of the second heat-dissipating metal structures extend along the vertical axis V towards the housing base 14 so as to be able to be interdigitated with the fins 32 of the first heat-dissipating metal structure 28.

In the context of the invention, the term ‘interdigitated’ should be interpreted as an insertion of the fins 32 of the first metal dissipating structures 28 between the fins 40 of the second metal dissipating structures 38. The cover 16 also comprises other heat-dissipating fins 44 on its external face 42 opposite to the printed circuit board 18 so as to optimize the heat dissipation. Preferably, these other heat-dissipating fins 44 situated on the external face 42 of the cover 16 and the heat-dissipating fins 40 of the second metal structures 38 all run in the same direction in order to facilitate the formation of the cover 16 by injection. It should however be noted that the other fins 44 placed on the external face of the cover 42 may not be essential to the electronic device 10, this optimisation depending notably on the thermal power to be dissipated.

According to FIG. 1, prior to assembly, pieces of a second heat-conductive material 46 with a globally rectangular shape, such as pieces of heat-conductive paste, are disposed in a plane fashion on the apices 33 of the heat-dissipating fins 32 of the first metal structures 28. The pieces of the second heat-conductive material 46 cover all of the fins 32 of the first heat-dissipating metal structures 28 and have a dimension along the transverse axis T greater than the dimension along the transverse axis T of the first heat-dissipating metal structures 28. According to FIG. 2, the dimensions of the second heat-conductive material 46, placed prior to assembly at the apex 33 of the fins 32 of the first metal structures 28, allow the second heat-conductive material 46 to be compressed between all the sidewalls 34 of the interdigitated fins 32, 40 of the first 28 and of the second dissipating metal structures 38 after assembly of the cover 16 of the housing 12 with the housing base 14.

According to FIG. 2, when the cover 16 of the housing 12 closes the housing 12 of the electronic device 10, the fins 32, 40 of the first and of the second heat-dissipating metal structures 28, 38 are interdigitated between one another in such a manner as to be thermally coupled together. The second heat-conductive material 46 situated on the sidewalls 34 of the interdigitated fins 32, 40 is a flexible material in such a manner as to be compressed between the interdigitated fins 32, 40 and therefore in contact with the interdigitated fins 32, 40. In other words, the gaps 37 between the interdigitated fins 32, 40 comprise the other heat-conductive material 46 disposed on the sidewalls 34 of the fins 32, 40 thus ensuring an efficient thermal coupling between the interdigitated fins 32, 40. The second heat-conductive material 46 forms a thermal seal between the interdigitated fins 32, 40. Preferably, the gaps 37 between the interdigitated fins 32, 40 have a dimension along the transverse axis T of less than a millimetre, the thickness of the second heat-conductive material 46 being greater than this dimension so as to be compressed between the interdigitated fins 32, 40. According to this assembly, a large part of the thermal energy of the elements producing heat 20, 22 is dissipated towards the outside of the housing 12. According to this assembly, in view of the characteristics of the second heat-conductive material 46 providing the coupling between the interdigitated fins 32, 40, the second heat-dissipating metal structures 38 forming part of the cover 16 do not require any specific fixing elements with the printed circuit board 18. This assembly also obviates the need for fixing screws between the heat-dissipating metal structures 28, 38 and the printed circuit board 18, thus reducing the risk of damaging the printed circuit board 18 or the elements producing heat 20, 22.

Alternatively, the second heat-conductive material 46 forming the thermal seals between the interdigitated fins 32, 40 may be replaced by heat-conductive grease of the metal oxide loaded silicone grease type previously disposed on the sidewalls 34 of the fins 32 of the first metal structures. As a further alternative, the second heat-conductive material 46 forming the thermal seals between the interdigitated fins 32, 40 may be a structure preformed with a shape complementary to the shape of the fins 32 of the first metal dissipating structures 28 so as to be placed between these fins 32 prior to the assembly of the cover 16.

The height of the electronic component 20 is generally of the order of one or a few millimetres, whereas the thickness of the conducting tracks 24 is equivalent to the thickness of copper used for the design of these high-current copper tracks, in other words a thickness of the order of a few tens or even hundreds of microns. The first two heat-dissipating metal structures 28 placed on the two elements producing heat 20, 22 have a fin height H1 similar to each other, whereas the second dissipating structures 38 protruding towards the inside of the housing 12 each have a different fin height H2. The differences in height H2 of the fins 40 of the second metal dissipating structures 38 allow the difference in distance between the elements producing heat 20, 22 and the internal surface of the cover 36 to be compensated so as to maintain the gap 37 between the interdigitated fins 32, 40 globally similar for all the heat-dissipating metal structures used for the electronic device, thus allowing the same thickness of the second heat-conductive material 46 placed between the interdigitated fins 32, 40 to be used.

Alternatively, the first metal dissipating structures 28 may have a height H1 of fin 32 different from each another in order to also compensate for the difference in height of the elements producing heat 20, 22. If necessary, it is also possible to have a height H1, H2 of fins 32, 40 different for each heat-dissipating metal structure 28, 38.

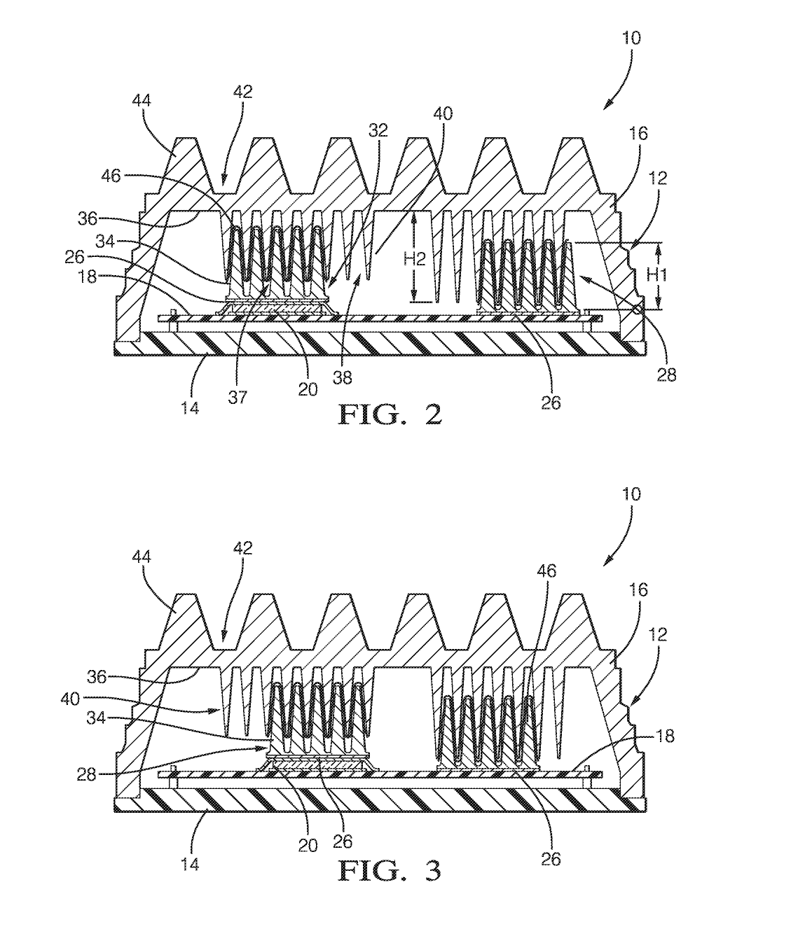

According to FIG. 2 and FIG. 3, the number of fins 40 of the second heat-dissipating metal structures 38 is greater than the number of fins 32 of the first heat-dissipating metal structures 28. One technical advantage of the greater number of fins 40 of the second heat-dissipating metal structures 38 is the flexibility offered in enabling the positioning of the electronic component 20 producing heat and of the area of the printed circuit board 22 traversed by high-current conducting tracks 24 to be modified or updated without having to develop a new housing cover 16. Preferably, this re-positioning is in the vicinity of the initial position of the elements producing heat. By virtue of this higher number of fins, in the case such as that shown in FIG. 3, in comparison with FIG. 2, despite the re-positioning of the electronic component 20 producing heat and of the area of the printed circuit board 22 traversed by high-current conducting tracks 24, the fins 32 of the first heat-dissipating metal structures 28 are all still interdigitated with the fins 40 of the second heat-dissipating metal structures 38. This higher number of fins 40 also allows flexibility in the dimensions of the elements producing heat.

According to other embodiments, the fins 32, 40 of the heat-dissipating metal structures 28, 38 may have shapes different from the shapes shown in FIGS. 1, 2 and 3. The fins 32, 40 of the metal dissipating structures 28, 38 must have geometrically complementary shapes in order to be able to be interdigitated whilst at the same time ensuring a thermal coupling between them by means of thermal seals formed by the heat-conductive material 46. The fins 32, 40 of each heat-dissipating metal structure 28, 38 may also be spaced apart from one another in a non-regular fashion if necessary. The fins 40 of the second metal dissipating structures 38 may also extend along the longitudinal axis to a greater extent than the fins 32 of the first heat-dissipating metal structures 28 so as to also allow a modification or updating of the positioning of the elements producing heat along the longitudinal axis or of the size of the elements producing heat.

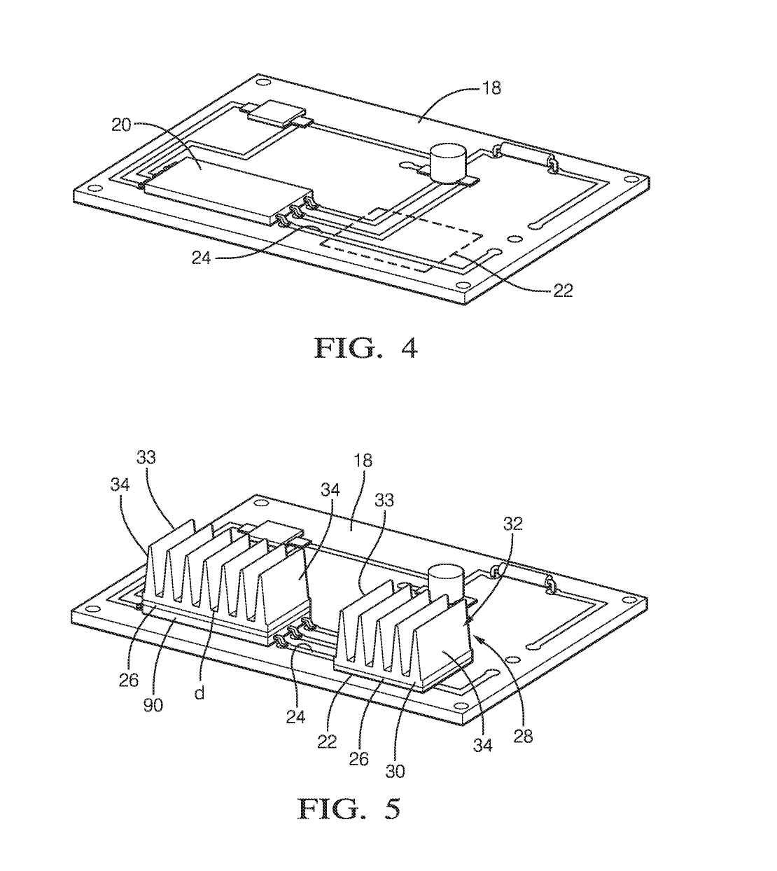

FIGS. 1, 4 and 5 show schematically one assembly of the electronic device 10 for motor vehicles. According to FIG. 4, the printed circuit board 18 comprises the electronic components 20 and the conducting tracks 22 connecting them together. The elements producing heat when the device is in operation have been determined. The elements producing heat identified are the area of printed circuit 22 traversed by conducting tracks 24 with high currents 22 such as modelled by the area framed with dashed lines in FIG. 3 and the electronic component 20 of the integrated circuit type. According to FIG. 5, the first heat-conductive material 26 has been placed on the surface of the elements producing heat 20, 22. According to FIG. 5, the first heat-dissipating metal structures 28 have been placed on the first heat-conductive materials 26 themselves placed on the elements producing heat. The first heat-dissipating metal structures 28 are held in place by virtue of the adhesive properties of the first heat-conductive material 26. According to FIG. 1, the printed circuit board 18 is placed on the housing base 14 and is held by fixing pins. According to FIG. 1, pieces of the second heat-conductive material 46 are placed in a plane fashion on the apices 33 of the heat-dissipating fins 32 of the first metal structures 28 in such a manner as to be able to be compressed between the fins 32 of the first metal structures 28 and the fins 40 of the second heat-dissipating metal structures 38 when the cover 16 of the housing 12 encloses the electronic device 10.

Alternatively, a structure of the second heat-conductive material 46 preformed with a shape complementary to the shape of the fins 32 of the first metal dissipating structures 28 may be placed between the fins 32 of the first metal dissipating structures 28 prior to the assembly of the cover 16.

Preferably, the electronic device 10 is enclosed by the cover 16 in a leak-tight manner.

While this invention has been described in terms of the preferred embodiments thereof, it is not intended to be so limited, but rather only to the extent set forth in the claims that follow.

We claim:

1. An electronic device for motor vehicles, said device comprising:
a heat-conducting housing containing a printed circuit board and an element producing heat mounted on the printed circuit board, said housing comprising a housing base on which the printed circuit board is mounted and comprising a cover opposite to the housing base, characterized in that a first heat-dissipating metal structure is mounted on the element producing heat, and in that a second heat-dissipating metal structure, which is formed as part of the cover of the housing and protruding into the housing, is coupled with the first heat-dissipating metal structure in such a manner as to facilitate the dissipation of the thermal energy from the element producing heat towards the outside of the housing.

2. The electronic device according to claim 1, wherein the first heat-dissipating metal structure and the second heat-dissipating metal structure each comprise a plurality of fins interdigitated with one another.

3. The electronic device 10 according to claim 2, wherein the interdigitated heat-dissipating fins comprise oblique sidewalls thermally coupled to one another.

4. The electronic device according to claim 2, wherein the first heat-dissipating metal structure comprises fewer fins than the second heat-dissipating metal structure.

5. The electronic device according to claim 2, wherein gaps between the interdigitated fins include a heat-conductive material in such a manner as to thermally couple the interdigitated fins.

6. The electronic device according to claim 2, wherein the printed circuit board comprises several first heat-dissipating metal structures with fins for which each height (H1) of each first metal structure with fins is adapted to the distance separating the element producing heat from the internal face of the cover of the housing in such a manner as to facilitate the dissipation of the thermal energy from the element producing heat towards the outside of the housing.

7. The electronic device according to claim 2, wherein the cover of the housing comprises several second heat-dissipating metal structures with fins for which each height (H2) of each second metal structure with fins is adapted to the distance separating the element producing heat from the internal face of the cover of the housing in such a manner as to facilitate the dissipation of the thermal energy from the element producing heat towards the outside of the housing.

8. The electronic device according to claim 1, wherein the first heat-dissipating metal structure is fixed onto the associated element producing heat by means of a heat-conductive adhesive layer.

9. The electronic device according to claim 1, wherein the cover of the housing comprises heat-dissipating fins on its external surface.

10. A method of assembling an electronic device for motor vehicles according to any one of the preceding claims comprising the steps for:
supplying a printed circuit board comprising elements producing heat;
fixing the printed circuit board onto a housing base;
fixing a heat-conductive material onto the elements producing heat;
fixing first heat-dissipating metal structures with fins onto the heat-conductive materials placed on the elements producing heat;
disposing another heat-conductive material on the fins of the first heat-dissipating metal structures fixed onto the elements producing heat;
supplying a cover for a heat-conductive housing comprising structures with fins protruding towards the inside of the housing; and
closing the housing by placing the cover of the housing on the housing base in such a manner as to interdigitate and to thermally couple the structures with fins of the cover of the housing with the structures with fins of the elements producing heat, the thermal coupling being implemented by compression of the heat-conductive material previously disposed on the fins of the first heat-dissipating structures between the sidewalls of the interdigitated fins.
